(19) United States
(12) Patent Application Publication
(10) Pub. No.: US 2014/0190727 A1
(43) Pub. Date: Jul. 10, 2014

(54) METHOD OF FABRICATING FLEXIBLE METAL CORE PRINTED CIRCUIT BOARD

(71) Applicant: STARLITE LED USA, Fremont, CA (US)

(72) Inventors: Emily Yu-Hsuan Lee, Fremont, CA (US); Pao Hsu Chen, Milpitas, CA (US); Chang Han, Fremont, CA (US)

(73) Assignee: Starlite LED USA, Fremont, CA (US)

(21) Appl. No.: 13/738,599

(22) Filed: Jan. 10, 2013

(51) Int. Cl. H05K 1/02; H05K 13/00

(52) U.S. Cl. CPC H05K 1/0201; H05K 1/0277; H05K 13/00
USPC 174/252; 174/254; 29/846

(57) ABSTRACT

A flexible metal core printed circuit board assembly comprises a flexible printed circuit board structure. The flexible printed circuit board structure includes a flexible substrate, a conductive layer on the flexible substrate and a space formed in the flexible printed circuit board structure. The space extends through the flexible printed circuit board structure. The flexible metal core printed circuit board assembly further comprises a flexible conductive structure having a pillar. The flexible conductive structure is provided underneath the flexible printed circuit board structure with the pillar disposed in the space. The pillar has a top surface that is in a planar surface with a top surface of the flexible printed circuit board structure.

### TECHNICAL FIELD

The example embodiments of the present invention generally relate to methods of fabricating printed circuit boards, and more particularly to designs and fabrication processes of flexible metal core printed circuit boards.

### BACKGROUND

Flexible printed circuits have been broadly used in consumer electronics due to their thinness and bendable flexibility. FIG. 1 shows a cross-sectional view diagram of a flexible printed circuit 100 of the prior art. The flexible printed circuit 100 includes a flexible substrate 102, an adhesive layer 104, a conductive layer 106 and a cover layer 108. The cover layer 108 covers surface of the flexible printed circuit except portions 110 that are used as electrode pads. Although a flexible printed circuit can be bent to form a multiple-facet circuit and therefore make many designs of consumer electronics possible, it suffers from poor thermal management due to the substrate material's low thermal conductivity. Poor thermal management may prevent flexible printed circuits from being used in high power electrical components, such as integrated circuits and light emitting diodes, due to insufficient thermal dissipation.

FIG. 2 illustrates a cross-sectional view of a flexible printed circuit 200 of the prior art. The flexible printed circuit 200 includes an additional adhesive layer 112 laminated between the flexible substrate 102 and a metal plate 114 disposed under the flexible substrate 102. The metal plate 114 may absorb some heat passing through the flexible printed circuit and then dissipate the heat into the air thus improving thermal dissipation. However, with such a structure, heat generated by components disposed on top surface of the flexible printed circuit will still be propagated through the flexible substrate. Due to relatively high thermal resistance of the substrate material, thermal dissipation may be insufficient and may result in overheating thus causing severe performance degradation or permanent damage to the components disposed on the top surface of the flexible printed circuit.

### BRIEF SUMMARY

According to one exemplary embodiment of the present invention, a flexible metal core printed circuit board assembly comprises a flexible printed circuit board structure. The flexible printed circuit board structure includes a flexible substrate, a conductive layer on the flexible substrate and a space formed in the flexible printed circuit board structure. The space extends through the flexible printed circuit board structure. The flexible metal core printed circuit board assembly further comprises a flexible conductive structure having a pillar. The flexible conductive structure is provided underneath the flexible printed circuit board structure with the pillar disposed in the space. The pillar has a top surface that is in a planar surface with a top surface of the flexible printed circuit board structure.

According to one exemplary embodiment of the present invention, a method of fabricating a flexible metal core printed circuit board assembly comprises providing a flexible printed circuit board structure. The method of providing a flexible printed circuit board includes providing a flexible substrate, forming a conductive layer on the flexible substrate and forming a space in the flexible printed circuit board structure. The space extends through the flexible printed circuit board structure. The method further comprises providing a flexible conductive structure underneath the flexible printed circuit board structure. The flexible conductive structure includes a pillar having a top surface. The method further comprises disposing the pillar in the space. The top surface of the pillar is in a planar surface with a top surface of the flexible printed circuit board structure.

### BRIEF DESCRIPTION OF THE DRAWING(S)

Having thus described the example embodiments of the present invention in general terms, reference will now be made to the accompanying drawings, which are not necessarily drawn to scale, and wherein:

FIG. 1 illustrates a cross-sectional view of a flexible printed circuit of the prior art;

FIG. 2 illustrates a cross-sectional view of a flexible printed circuit of the prior art;

FIG. 3A illustrates a cross-sectional view of a flexible printed circuit structure according to an example embodiment of the present invention;

FIG. 3B illustrates a top view of a flexible printed circuit structure according to an example embodiment of the present invention;

FIG. 4 illustrates a conductive structure according to an example embodiment of the present invention;

FIG. 5 illustrates a flexible metal core printed circuit board assembly according to an example embodiment of the present invention;

FIG. 6 illustrates a cross-sectional view of assembling an exemplary flexible metal core printed circuit board assembly with a light emitting diode package according to an example embodiment of the present invention; and

FIG. 7 illustrates a cross-sectional view of an omni-directional illumination module according to an example embodiment of the present invention.

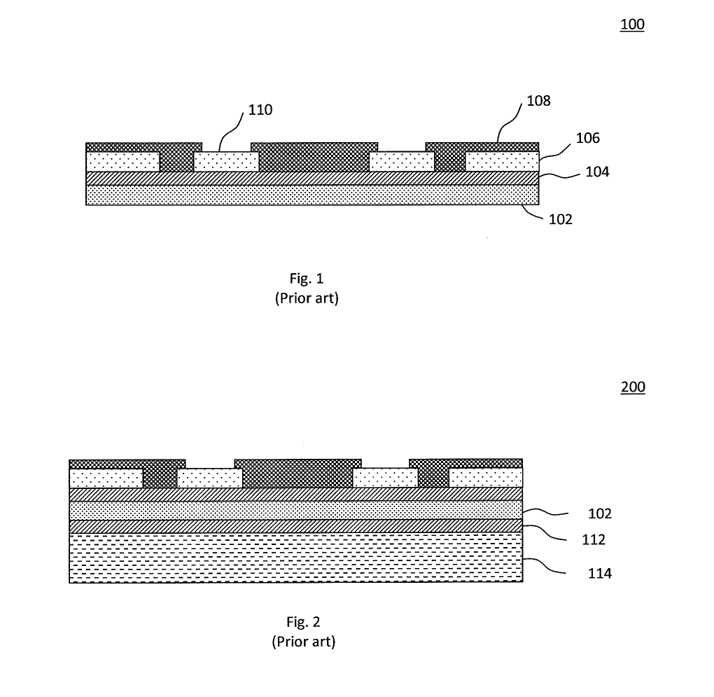

### DETAILED DESCRIPTION

The present disclosure now will be described more fully with reference to the accompanying drawings, in which some, but not all embodiments of the disclosure are shown. This disclosure may be embodied in many different forms and should not be construed as limited to the embodiments set forth; rather, these example embodiments are provided so that this disclosure will be thorough and complete, and will fully convey the scope of the disclosure to those skilled in the art. Like numbers refer to like elements throughout.

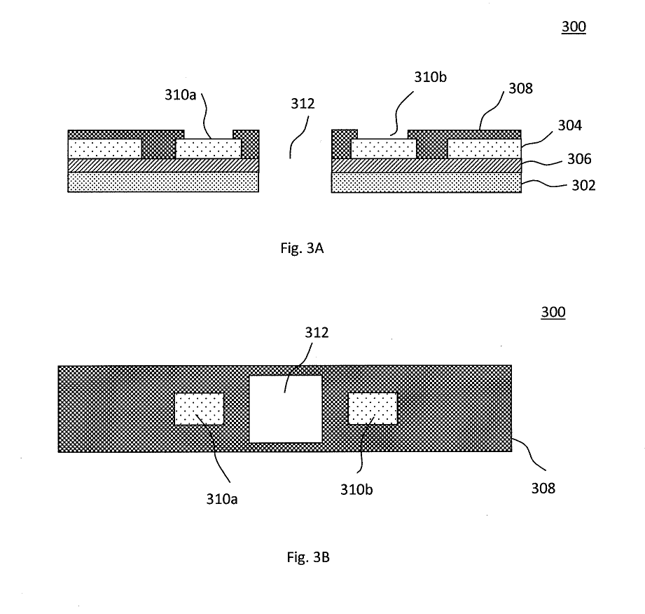

FIG. 3A illustrates a cross-sectional view of a flexible printed circuit board structure 300 according to an example embodiment of the present invention (“example,” “exemplary” and like terms as used herein refer to “serving as an example, instance or illustration”). The flexible printed circuit structure 300 may include a flexible substrate 302 and a conductive layer 304. The flexible substrate 302 may comprise dielectric material. The dielectric material may comprise one or more of polyester, polyimide, polyethylene napthalate, polyetherimide, fluropolymers, and/or any other suitable dielectric material. The conductive layer 304 may be deposited on the flexible substrate 302 by applying evaporation, sputter deposition, spray deposition, airbrushing, screen-printing, photolithograph, and/or any other suitable processes, to pattern electronic circuits on the flexible substrate 302. In one embodiment, the conductive layer 304 may be metal foil, for example, a copper foil, and/or may comprise at least one of Tin, zinc, silver, indium, nickel and/or any other suitable conductive material that are ductile and easily bent when deposited as thin films. The conductive layer may be conductive paste or conductive epoxies for bonding to the substrate. Depending on the material of the flexible substrate, and/or the material of the conductive layer, flexible metal core printed circuits may or may not comprise a bonding medium between the flexible substrate and the electronic circuits. In various examples, a flexible printed circuit board structure may be fabricated with or without protective coatings. To facilitate explanation of the invention, the description will be focused on a method of fabricating a flexible metal core printed circuit structure including a circuit adhesive layer and a cover layer, but the method (and/or aspects thereof) may be easily applied to or adapted for a flexible printed circuit structure that does not include the circuit adhesive layer and/or the cover layer or a flexible printed circuit that includes additional layers other than the circuit adhesive layer and cover layer. For example, an exemplary embodiment may include two or more adhesive layers.

Referring back to FIG. 3A, the flexible metal core printed circuit structure 300 comprises a circuit adhesive layer 306 used as the bonding medium that is provided over the flexible substrate 302 prior to applying the conductive layer 304. In this regard, the circuit adhesive layer 306 is laminated between the flexible substrate 302 and the conductive layer 304. The adhesive layer may comprise conductive adhesives provided directly from a commercial vendor, such as aerosol-based adhesive, water-based adhesive, and/or any other suitable adhesive that can provide adhesion to the substrate. The flexible metal core printed circuit structure 300 may also comprise a cover layer 308 provided as the protective coatings to cover portions of the electronic circuits to protect surface features of the electronic circuits, except some specific areas used as electrode pads (e.g., 310a and 310b) that are configured to be coupled with electric components that may be disposed on top of the flexible metal core printed circuit structure. In one example, the cover layer 308 may be a solder resist layer. In another example, the cover layer 308 may be a coverlay. The cover layer 308 may comprise one or more protective materials, for example, polyimide, polyethylene terephalate, polyethylene naphthalate, and/or other suitable materials.

A space 312 is formed in the flexible printed circuit board structure 300 by selectively removing part of the flexible substrate 302, the circuit adhesive layer 306, the conductive layer 304 and the cover layer 308. In this regard, the space 312 may extend through the flexible metal core printed circuit board structure 300. The space 312 may be formed by applying mechanical methods, for example, mechanical punch, drilling and carving and/or chemical methods, such as chemical etching, and/or any other suitable methods that can selectively remove materials from the flexible substrate, the conductive layer and/or the circuit adhesive layer and the cover layer. The space 312 may be formed between two adjacent electrodes pads (e.g., electrode pads 310a and 310b in this embodiment).

FIG. 3B illustrates a top view of the flexible printed circuit structure 300 according to an example embodiment of the present invention. As shown in FIG. 3B, the electrode pads 310a and 310b are not covered by the cover layer 308. The space 312 extends through the flexible printed circuit structure 300 and is formed between the adjacent electrode pads 310a and 310b.

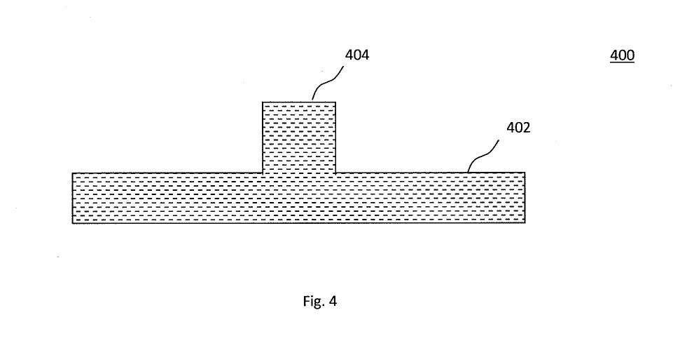

To accelerate heat dissipation propagated from electronic components through the flexible printed circuit board structure, a conductive structure may be provided underneath the flexible printed circuit structure 300. As shown in FIG. 4, a flexible conductive structure 400 may include a flexible conductive plate 402 with a pillar 404 formed on it. The pillar 404 may be formed by a mechanical process, for example, a computer numerical control milling, mechanical punching, molding, forging, and/or any other suitable mechanical processes. The pillar 404 may also be formed by a chemical process, such as a photolithography processes, and/or any other suitable chemical process. When the flexible conductive structure 400 is assembled with a flexible printed circuit board, the flexible conductive structure 400 is provided underneath the flexible printed circuit structure with the pillar 404 disposed in a space (e.g., space 312 shown in FIG. 3A) formed in the flexible printed circuit structure. To make a top surface of the pillar 404 in a planar surface with a top surface of the flexible printed circuit board structure (e.g., surface of the cover layer 308 shown in FIG. 3A), size and shape of the pillar 404 may vary with changes in size and/or shape of the space. Shape of the pillar is not limited to a cuboid as shown in this embodiment. The pillar can be a cube or other shapes that has a planar top surface. In one embodiment, the flexible conductive structure 400 may be made of metal, for example, metal alloy, and/or may comprise at least one of copper, aluminum, graphite, ceramic, polymer and/or any other suitable metal material.

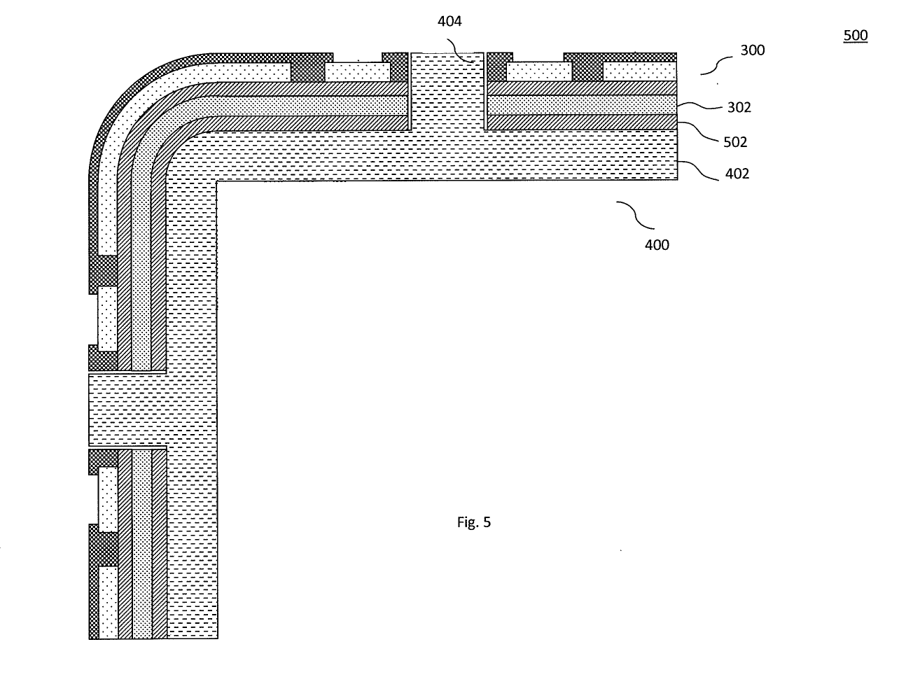

FIG. 5 illustrates a flexible metal core printed circuit board assembly 500 according to an example embodiment of the present invention. The flexible metal core printed circuit board assembly 500 may include a flexible printed circuit structure (e.g., the flexible printed circuit structure 300 show in FIGS. 3A and 3B) and a flexible conductive structure (e.g., the flexible conductive structure 400 shown in FIG. 4). In some examples, a structure adhesive layer may be provided between the flexible conductive structure and the flexible printed circuit board. For example, when the flexible conductive structure 400 is assembled with the flexible printed circuit board structure 300, a structure adhesive layer 502 is sandwiched between the flexible substrate 302 and the flexible conductive plate 402.

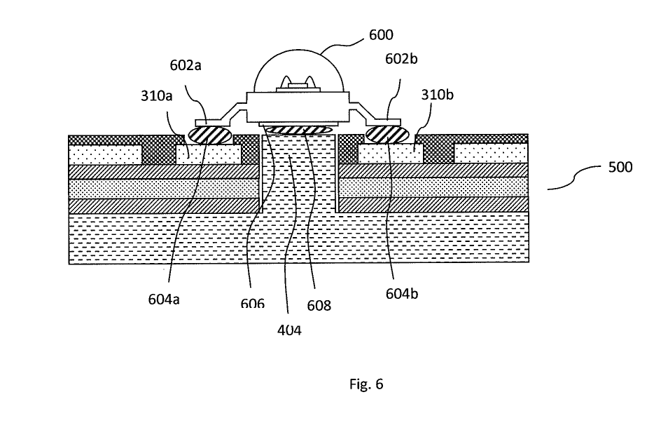

An electronic component, for example, a light emitting diode package, may be assembled with an exemplary flexible metal core printed circuit board assembly. A cross-sectional view of assembling the flexible metal core printed circuit board assembly 500 with a light emitting diode package 600 is illustrated in FIG. 6 according to an example embodiment of the present invention. Anode 602a and cathode 602b of the light emitting diode package 600 may be respectively coupled to the electrode pads 310a and 310b by filling solder 604a in space between anode 602a and electrode pad 310a, and solder 604b in space between cathode 602b and electrode 310b using one of reflow process, thermal cure, ultrasonic and ultraviolet methods. Similarly, the top surface of the pillar 404 may be coupled to a thermal pad 606 that is deposited on a bottom surface of the light emitting diode package 600 via solder 608. The solders 604a, 604b and 608 may be replaced by or used in combination with one of conductive bonders, thermal-conductive epoxy, thermal grease, solder paste, and/or other conductive paste.

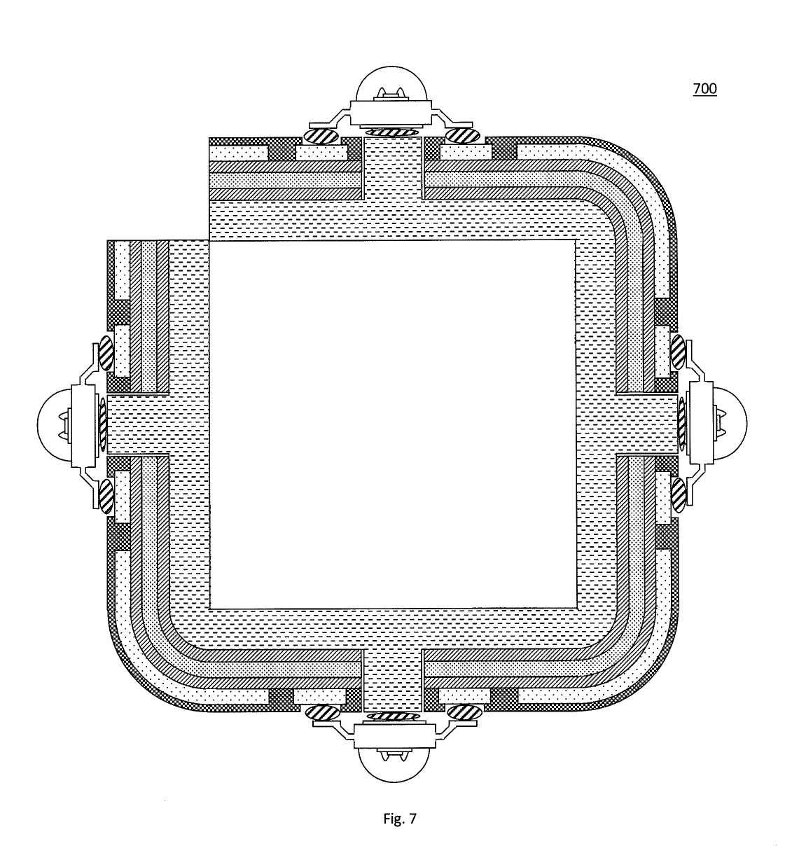

Flexible metal core printed circuit board assembly (e.g., the flexible metal core printed circuit board assembly 500 illustrated in FIG. 5) may be folded or creased (repeatedly) by about an angle, for example, 30 degrees or 90 degrees, shaped to form three dimensional structures. For example, as illustrated in FIG. 7, a flexible metal core printed circuit board assembly may be bent by about 360 degrees to form a rectangular. At least one light emitting diode package is mounted on each side of the rectangular thus creating an omni-directional illumination module 700.

Many modifications and other example embodiments set forth herein will come to mind to one skilled in the art to which these example embodiments pertain having the benefit of the teachings presented in the foregoing descriptions and the associated drawings. Therefore, it is to be understood that the embodiments are not to be limited to the specific ones disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions other than those explicitly described above are also contemplated as may be set forth in some of the appended claims. Although specific terms are employed herein, they are used in a generic and descriptive sense only and not for purposes of limitation.

That which is claimed:

1. A flexible metal core printed circuit board assembly, comprising:
a flexible printed circuit board structure, including
a flexible substrate;
a conductive layer on the flexible substrate, a space formed in the flexible printed circuit board structure, the space extending through the flexible printed circuit board structure; and
a flexible conductive structure having a pillar, wherein the flexible conductive structure is provided underneath the flexible printed circuit board structure with the pillar disposed in the space, the pillar having a top surface being in a planar surface with a top surface of the flexible printed circuit board structure.

2. The flexible metal core printed circuit board assembly of claim 1, wherein the flexible printed circuit board structure further comprises a circuit adhesive layer laminated between the flexible substrate and the conductive layer.

3. The flexible metal core printed circuit board assembly of claim 1, wherein the flexible printed circuit board structure further comprises a cover layer provided over the conductive layer.

4. The flexible metal core printed circuit board assembly of claim 1, further comprising a structure adhesive layer disposed between the conductive structure and the flexible printed circuit board structure.

5. The flexible metal core printed circuit board assembly of claim 1, wherein size and shape of the pillar is determined by the space.

6. The flexible metal core printed circuit board assembly of claim 1, wherein the top surface of the pillar is coupled to an electronic component disposed on the top surface of the flexible printed circuit board structure by filling one of solder, conductive bonders, thermal-conductive epoxy, thermal grease and solder paste between the top surface of the pillar and a bottom surface of the electronic component.

7. The flexible metal core printed circuit board assembly of claim 1, wherein the flexible substrate comprises dielectric material.

8. The flexible metal core printed circuit board assembly of claim 1, wherein the flexible substrate comprises one of polyester, polyimide, polyethylene napthalate, polyetherimide and fluropolymers.

9. The flexible metal core printed circuit board assembly of claim 1, wherein the conductive layer comprises at least one of metal foil, conductive ink and plated metal.

10. The flexible metal core printed circuit board assembly of claim 1, wherein the conductive layer comprises one or more of Tin, zinc, silver, indium, gold, aluminum, copper and nickel.

11. The flexible metal core printed circuit board assembly of claim 1, wherein the flexible conductive structure comprises at least one of metal, metal alloy, graphite, polymer and ceramic.

12. A method of fabricating a flexible metal core printed circuit board assembly, comprising:
providing a flexible printed circuit board structure, including
providing a flexible substrate;
forming a conductive layer on the flexible substrate;
forming a space in the flexible printed circuit board structure, the space extending through the flexible printed circuit board structure;
providing a flexible conductive structure underneath the flexible printed circuit board structure, the flexible conductive structure including a pillar having a top surface; and
disposing the pillar in the space, wherein the top surface of the pillar is in a planar surface with a top surface of the flexible printed circuit board structure.

13. The method of claim 12, further comprising applying a printing process to the conductive layer to pattern electronic circuits.

14. The method of claim 13, wherein the printing process comprising one of evaporation, sputter deposition, spray deposition, airbrushing, screen-printing and photolithograph.

15. The method of claim 13, further comprising providing a circuit adhesive layer laminated between the flexible substrate and the conductive layer.

16. The method of claim 12, further comprising providing a cover layer over the conductive layer.

17. The method of claim 12, further comprising providing a structure adhesive layer between the flexible conductive structure and the flexible printed circuit board structure.

18. The method of claim 12, further comprising selectively removing a portion of the flexible metal core printed circuit board structure by applying one of mechanical punch, drilling, carving and chemical etching to form the space.

19. The method of claim 12, further comprising fabricating the pillar by one of computer numerical control milling, photolithography processes, mechanical punching, molding and forging.
